(19) United States
(12) Patent Application Publication
(10) Pub. No.: US 2008/0142828 A1
(43) Pub. Date: Jun. 19, 2008

(54) Coaxial light-guide system consisting of coaxial light-guide fiber basing its refractive index profiles on radii and with its coaxial both semiconductor light sources and semiconductor detectors

(76) Inventor: Chun-Chu YANG, Kaohsiung City (TW)

Correspondence Address: Frenkel & Associates, P.C., Suite 330, 3975 University Drive, Fairfax, VA, 22030, US

(21) Appl. No.: 12/001,131

(22) Filed: Dec. 10, 2007

(30) Foreign Application Priority Data
Dec. 15, 2006 (TW) 095146963

(51) Int. Cl. H01L 33/00; G02B 6/036; H01L 31/00

(52) U.S. Cl. 257/98; 385/127; 257/432; 257/E33.067; 257/E31.127

(57) ABSTRACT

A coaxial light-guide system includes a coaxial light-guide optical fiber which is fabricated by having refractive index profile set on radii. Thus the coaxial circular outer-cladding and the axial inter-cladding have the same refractive index. The light guide refractive index profile center is moved from the axis to the entire radii of the optical fiber. Light propagates between the axial inter-cladding and the coaxial circular outer-cladding. Such a new positioning prevents center-dip in the refractive index profile that occurs to the prior optical fiber after fabrication is finished. The coaxial single-mode optical fiber of the invention has a greater optical flux than the prior optical fiber, and can increase communication distance. Coupled with a coaxial light source and photodiode of the invention that have an coaxial inner and outer conductors to supply electric power and a plurality of annular semiconductor layers interposed therebetween, energy waste caused by prior edge-emitting elliptic light source injecting in a circular core can be eliminated.

### FIELD OF THE INVENTION

The present invention relates to a communication optical fiber and particularly to a coaxial light guide system equipped with a light source and a photodiode.

### BACKGROUND OF THE INVENTION

Human being discovered glass about 2500 years ago, and learned to draw fibers from the glass until at Roman time. In 1950 medical field tried to bind bare glass fibers into a bundle to transmit images to be used as an endoscope. But light leakage was too much and images could not be clearly transmitted. It was mainly because the bare glass fibers did not have a desired purity and the external air that has a lower refractive index serves as a total reflective layer. In 1956 Dr. Narinder Singh Kapany first coined the term “fiber optical”. By wrapping more precisely a layer of glass material of a lower refractive index around a bare glass fiber as an outer shell total reflection was controlled more effectively and light leakage was prevented. As a result the optical fiber can transmit light and images fully to make endoscope possible. Ever since optical fiber was formed by including an inner layer and an outer layer that have different refractive indices. And various types of optical fibers have been designed and fabricated by basing on the entire diameter as the refractive index profile for light guiding. The bare glass fibers originally located inside that have a greater refractive index become the main portion of light guide and were called the “core” of the optical fiber, while the outer shell which has a lower refractive index was called the “cladding ” of the optical fiber. Those names were adopted universally ever since. The “ray theory” which states that light travels in an undulate and total reflective model in the optical fiber is accepted by the public. And its geometric optical physics also is applied down to date.

Refer to FIG. 1 for a prior optical fiber structure. It has a core 101 and a cladding 102. FIGS. 2A, 2B and 2C illustrate light travel conditions in the optical fiber. FIG. 2C shows a multimode step index optical fiber, FIG. 2B shows a multimode graded index optical fiber, and FIG. 2A shows a single-mode optical fiber. All the optical fibers mentioned above are drawn from glass initially and formed naturally to become a circular waveguide. In 1963, STL Karbowiak of U.K. announced a Flexible thin-film waveguide theory that has a slab waveguide formed in a thin dielectric structure to transmit optical wave in a single-mode model. However, referring to light propagation in a dielectric film that is supported by a frame and surrounded by air space, as the refractive indices of the film 301 and the air medium 302 at the upper side and lower side differ greatly, unless the film is formed extremely thin transmission loss is too much to make practical use possible. Hence such an approach was abandoned. Same as FIG. 3A, efforts attempted to realize slab waveguide continued, such as U.S. Pat. No. 3,386,787 entitled “Macroscopic optical waveguides” by R. A. Kaplan in 1968, and U.S. Pat. No. 3,659,916 entitled “Single-mode dielectric waveguide” by Marctili et al assigned to U.S. Bell Lab. in 1970 as shown in FIG. 3B, all proposed a single-mode waveguide system formed in a slab structure to accomplish propagation. U.S. Pat. No. 3,806,223 entitled “Planar optical waveguide” by Keck et al assigned to Corning Co. in 1974, also discloses a slab waveguide structure and related manufacturing method. Prior to that, in 1964, Charles K. Kao and George Rockham of U.K. STL abandoned the thin film waveguide and inclined to adopt single-mode circular waveguide optical fiber. In 1966, after finding out the main causes of loss in glass, proposed an improved manufacturing technique and to reduce the content of transient metal ions that are the main cause of loss in the glass lower than 1 ppm, as a result absorption loss drops below 20 dB/Km. The optical fiber at such a low loss could be used for long distance communication. That theory was proved a few years later. As a result, the direction of optical fiber development and manufacturing was set. And a whole new field of optical fiber communication was immediately unfolded.

The method for manufacturing the prior optical fiber usually includes fabricating a preform first. The preform has a cross section structure same as that of the tiny optical fiber after drawing is finished.

The manufacturing process of communication glass (quartz) optical fiber general includes two techniques, namely fabricate a preform rod with a cross section mentioned above and drawing fibers. In the present well developed optical fiber manufacturing technique, before the optical fiber is drawn to become at a very small diameter of 125 μm or other specifications it is enlarged proportionally to form a optical fiber preform at a diameter about 2 cm to 4 or 5 cm. Then it is placed in a high temperature oven to be drawn into a fine fiber. Almost all the factors related to the internal refractive index profile and propagation characteristics of different optical fiber types such as material selection, geometric arrangement, optical characteristics are set at the preform state. Hence the manufacturing technique to fabricate the preform is the key and critical technique of optical fiber manufacturing.

In the last twenty years, the techniques known in the industry to fabricate the preform mainly can be divided into two categories and four methods. The two categories are IVPO (Inside Vapor-Phase Oxidation process) and OVPO (Outside Vapor-Phase Oxidation process). The IVPO further includes two methods, namely MCVD (Modified Chemical Vapor Deposition) and PCVD (Plasma-activated Chemical Vapor Deposition). The Applicant owns a R.O.C. patent No. I 261073 granted in 2004 related to VLSD. It is a vertical large scale synchronous inside deposition method to fabricate optical fiber preform in large quantity.

The OVPO further includes OVD (Outside Vapor Deposition) and VAD (Vapor-phased Axial Deposition) to fabricate the preform. References of the methods for manufacturing the preform are available in the aforesaid patents.

The optical fiber for communication has capability to transmit electromagnetic (optical) wave from one end to a remote end. As previously discussed, the traditional optical fiber is a fine and evenly transparent material, but has arranged refractive index variations on the cross section. For instance, the core in the center that has a higher refractive index is surrounded by the cladding which has a lower refractive index. Such an optical fiber can be fabricated by encasing the core made from doped silicon to increase the refractive index with a pure silicon cladding made from fused silica. Through such a structure light is confined in the core and transmitted between the core and cladding under total reflection. Such type of optical fiber usually has an optical wave higher than one mode confined in the core during transmission. It is named multimode. Each mode has a different path and speed for transmission. Such a phenomenon often makes the pulse width wider at the output end. It is called dispersion.

The dispersion occurred in the multimode is the main cause of group delay. This results in a lower bandwidth. To increase the bandwidth there is a technique by forming a parabola core in a graded index multimode optical fiber so that various modes of different speeds form an optical self-focusing as shown in FIG. 2B. However, fabricating the parabola core to get a desired refractive index profile to achieve a theoretical optimum bandwidth is very difficult, and a lot of issues have to be addressed, such as increasing the distance from the core where the refractive index is highest to the outer side the doped quantity has to be reduced gradually, the accuracy, reproducibility and complexity of equipment to control the doped quantity are big problems, and ripple being generated while the refractive index is gradually changed also is a troublesome issue. Finally, in order to make various modes to have a same speed so that they can start at the same time and arrive the remote end also at the same time to achieve communication object, the core has to be shrunk to the Fundamental Mode in which light propagation is confined in the core to eliminate mode dispersion. It becomes a single-mode optical fiber. At present except for a very short distance such as a LAN in which the grade index multimode optical fiber can be adopted, more than 90% of optical fibers in the market for communication are single-mode optical fibers. Hence single-mode optical fiber is the main product for optical fiber communication. In the single-mode optical fiber the core is the main medium for transmitting optical wave. Its area takes only 1% of the total optical fiber size. The rest 99% serves as a reflective layer for total reflection and provides strength support. This is not an efficient utilization. Take into account of the strength of the optical fiber and easy splicing operation without changing the outer diameter of 125 μm of the traditional optical fiber, the single-mode optical fiber still has a lot of usable area. There is no reason to confine the utilization as it is and not to take more advantages of its untapped capacity. For instance, by boosting the Optical Flux of the single-mode optical fiber more photon energy can be provided at the receiving end to increase power energy supply at the receiving end. Then the photodiode of a given sensitivity can be moved to a receiver at a longer distance to increase the transmission distance, or the photodiode of the same sensitivity can be coupled with a lower power laser light source to reduce system cost, or a photodiode of a lower sensitivity can be selected to reduce the system cost and increase the communication distance. All this can help to reduce waste of the fine and pure semiconductor resources.

On optical communication, aside from demanding system cost effectiveness, try to install and use flawless products also is a common goal and expectation. However, based on decades of experiences in optical fiber manufacturing, especially fabricating optical fiber from a preform collapsed by IVPO, the center-dip problem often occurs on the center of the refractive index profile whether on single-mode optical fiber or multi-mode optical fiber as shown in FIGS. 4A and 4B.

FIG. 4A illustrates the center-dip of the refraction index profile in a single-mode optical fiber, and FIG. 4B illustrates the center-dip of the refraction index profile in a graded index profile. At present among the main manufacturing methods of MCVD, PCVD, OVD and VAD for optical fiber preform, the former threes types have this problem. MCVD and PCVD proceed collapsing after having finished about hundreds or thousands of layers through inside deposition steps (while a hollow condition still exists, and is called a preform tube). OVD proceeds dehydration and sintering process after having finished about hundreds or thousands of layer through outside deposition steps (while a small hollow condition still exists, and also may be called a preform tube). On the deposited layers at the hollow portion where a solid core is not yet formed, a great amount of doped material GeO₂ evaporates and results in depressed of the refractive index profile center. It is a troublesome issue in the industry not yet being fully overcome.

Doping GeO₂ on the core aims to increase refractive index. But dispensed during collapsing or sintering process at a higher deposition temperature, it evaporates and its concentration in the pure silicon is reduced. As a result, the original expected refractive index value cannot be achieved. Hence center-dip of refractive index profile impairs optical fiber transmission characteristics, whether it is single-mode optical fiber or multi-mode optical fiber. This shortcoming cannot be totally attributed to the three types of optical fiber preform manufacturing processes mentioned above. As the traditional technique by basing on the entire diameter as the refractive index profile for light guiding, the higher refractive index portion of the refractive index profile center is exposed and heated for a long time period during manufacturing process, and GeO₂ doping evaporates at the high temperature in the final manufacturing process. Thus the problem of depressed occurs to the refractive index profile center(called center-dip too).

The traditional technique that fabricates the optical fiber with the diameter as the basis of light guide refractive index profile, aside from incurring center-dip of the refractive index profile, also has a lower manufacturing efficiency due to quality control of the preform and fiber drawing cannot be performed immediately after the hollow preform tube has been formed through the inside deposition process of the MCVD and all deposition layers have been finished through the method of PCVD. Moreover, the hollow core is not being protected before collapse, and contamination easily takes place during various operation procedures and fiber drawing. Hence after the solid core is formed the characteristics could be damaged significantly. In addition, the concentration of GeO₂ which is doped to increase the refractive index increases gradually from outer side to inner side and reaches the highest level at the core. But material expansion coefficient increase gradually from the outer side to the inner side until reaching the hollow portion. Such an uneven material expansion coefficient at the inner side and outer side also occurs to the preform tube. As a result, the preform tube frequently cracks due to alterations of manufacturing process or excessive temperature variations of the environment. To overcome these problems, the preform has to be directly collapsed to form the solid core and moved out for quality control and fiber drawing. All this creates a lot of problems.

The problem of center-dip in the refractive index profile_that results in a lower bandwidth commonly happens to multi-mode optical fiber. This is especially serious on the graded index multimode optical fiber for LAN. Although some techniques have been developed by shooting laser to an outer annular portion of the core or adopts ring core hollow fiber to compensate imperfect waveguide caused by center-dip of the refractive index profile, they merely a makeshift measure applied to tubular optical fiber, but cannot thoroughly increase the bandwidth. On the single-mode optical fiber, as its core is formed at a very small diameter, the depressed portion takes a greater proportion of the total uneven refractive index, impact is even greater. Hence although the techniques of compensating the center-dip in the refractive index profile are available, applying them is tedious and time consuming, and the result is still not desirable.

The high bandwidth characteristics of the single-mode optical fiber provides highest quality in optical fiber communication. As the single-mode optical fiber has a very small core to transmit optical energy, the optical flux passing through the core of the prior single-mode optical fiber is very small. To transmit a longer distance has to rely a greater power laser source to focus and shrink the light spot to enter the core of the optical fiber. The intensified edge-emitting laser shown in FIG. 5 provides an elliptic light radiation waveform 505 focused to enter the small circular core. It is against the natural law, and results in waste of power, and needs more expense to add control circuit and equipment to cool the high temperature generated by greater current. As a result system cost is higher. In FIG. 5, symbols 501 represent electrodes, 502 for a substrate, 503 for an active layer, 504 for an emission area, and 506 for a SiO₂ insulation layer

Vertical Cavity Surface Emitting Laser (VCSEL), referring to FIG. 6, provides a circular emission wave mating the circular core. But it has fine deposited layers or epitaxy growth layers 601 and 605 distributed at the upper side and lower side to serve as a Bragg reflective mirror DBR optical grating, (with symbol 602 for an active layer, 603 for a buffer layer, and 606 for an annular electrode), voltage drops during passing through these fine layers, especially the hetero junction, if elements of epitaxy layer with λ/4 higher refractive index and λ/4 lower refractive index are forward biased, a non-continuity of an energy band is ensued and results in hindering of current flow. And the current becomes unstable. As a result, it is difficult to boost power and provide higher power output. Hence it cannot substitute the edge-emitting laser. But the edge-emitting laser provides elliptic light output, try to mate the circular core is against the natural law.

### SUMMARY OF THE INVENTION

The previous discussion indicates that the traditional optical fiber fabricated through the prior techniques and the light source and photodiode being adopted have the following six disadvantages, as a result the prior optical fiber, light source and detector used on optical communication cannot be fully integrated as desired to achieve optimal result:

1. The prior optical fiber fabricated through the methods of MCVD, PCVD and OVD cannot form a desired refractive index profile center. Around the refractive index profile center where the refractive index is highest deposition has been finished for a number of layers, but the axis portion is still hollow. The hollow portion is gradually collapsed under high temperature to become a solid core. During this process the deposited layers are not shielded or protected. A great amount of the doped material GeO₂ which aims to increase the refractive index evaporates. As a result the refractive index is lower than the expected level. And depressed is formed on the refractive index profile center, thus light guide in the center is not desirable.

2. Exposition of the inner layer of the preform tube makes prior quality control not possible and results in waste of collapse process cost. To fabricate the prior optical fiber preform through the methods of MCVD and PCVD, when the deposition has been finished for a number of layers around the refractive index profile center where refractive index is highest, the axis portion where the core is intended to be formed is still hollow. Before the hollow portion is collapsed to become a solid preform, to move it to the ordinary environment to do quality control and inspect the refractive index is difficult unless a very strict temperature protection environment is provided. This is especially true for MCVD and PCVD methods in which the hollow portion of the preform has a larger internal diameter that is not protected. A direct collapse process has to be adopted to prevent contamination of the most important core and absorption loss of OH ions, and difference of internal and external stress that could cause crack. Due to the inner layer of the preform tube is exposed and the direct collapse process has to be adopted, and the collapse process has been performed for a number of hours, to prevent depressed and deformation caused by impact of high temperature gas while the exterior of the preform tube is heated, gas must be injected to keep a constant internal pressure to maintain the genuine circle of the preform and the drawn optical fiber. This internal gas flow for a prolonged period of time incurs other problems such as leakage of gas and moisture content of the gas injection system. As a result OH content in the core of the optical fiber often increases and loss also is higher.

3. The single-mode optical fiber which provides maximum bandwidth has too small of core which is difficult to connect. It also results in a lower utilization of the light guide material and waste of the highly pure material resources. It is not environmental friendly and does not fully utilize the fine and pure material. The single-mode optical fiber adopted at present for optical communication that provides maximum bandwidth has a very small core, with a diameter about 10 μm. Its light guide core area is less than 1% of the cross section of the optical fiber. 99% of the cross section provides support. Hence the ratio (A) of effective utilization area in an unit area is too low and result in waste of fine and pure material resources. For instance, for a single-mode optical fiber with an outer diameter of 125 μμm and the core diameter of 10 μm, the effective area utilization ratio of the light guide material A=5²π/62.5²π×100%=0.64%. It is too low and does not fully utilize the available capability of the single-mode optical wave propagation to achieve communication purpose.

4. As the prior single-mode optical fiber has too small of light guide area in the core, not only optical flux is lower and operable distance is shorter, a stronger laser with an elliptic radiation waveform has to be provided for focusing to enter the circular and small core structure. It is against natural law and results in a higher system cost. As the single-mode optical fiber adopted in the traditional optical fiber communication that provides maximum bandwidth has a very small size of core, light guide area also is small, and the aperture is tiny, hence a strong intensity laser light source has to be provided and focused through a lens, then project to the small and circular core to achieve a longer distance transmission. The laser is more expensive. The expense of control circuit increases and equipments for cooling have to be provided. All this makes system cost higher.

5. Mating the elliptic radiation waveform and the circular optical fiber core is a problem. The high intensity laser at present is an edge-emitting type. It generates elliptic radiation waves that cannot fully mate the wave guide of the circular core. Hence power waste occurs. Moreover, the elliptic light from the start has vertical and horizontal electric field amplitudes with unequal polarization-mode variations. After entering the optical fiber and propagating for a long distance, due to the initial variations of the vertical and horizontal polarized value of the light source, and internal stress difference caused by geometric unevenness of the lengthy wave guide structure of the optical fiber, and stress generated during fabrication of the optical fiber cabling process, polarization-mode dispersion (PMD) takes place at the receiving end. This problem seriously affects bandwidth during high speed communication.

6. Problem of mating light intensity distribution output by the optical fiber and light detection performance of the photodiode. The prior optical fiber outputs light with the intensity distributed in a Gaussion distribution shape that is strongest at the core and the intensity gradually decreases as the distance from the core increases. The optical communication mostly adopts front illuminated photodiode. Its surface electrode is an annular electrode as shown in FIG. 7 (where symbol 701 represents a depletion layer, 702 is a SiO₂ insulation layer, 703 is an annular electrode, 704 is an anti-reflection layer, 705 is a p-type semi-conductor layer, 706 is electric field distribution, 707 is photon injection, 708 is a n-type substrate). When the surface annular electrode 703 and the planar electrode at the bottom layer provide electricity of an inverse bias voltage to the semiconductor of each layer interposed between them, as the inner rim end surface of the hollow annular electrode at the upper surface has a higher electron density, and current travels through the shortest distance, the electrons and electric holes at the depletion layer form an electric field distribution with a potential barrier, and the center area at the axis is lower than the outer annular area and forms an uneven condition. Pairs of electron and electric hole are generated when stimulated. And uneven distribution is formed due to the inner electric field of the depletion layer 701 is smallest at the axis portion and gradually increases towards the outer annular portion. While the optical fiber output is strongest in the center and the optical signal is distributed according to Gaussion distribution, it enters the photodiode which has a lower efficiency in the center. Such a mating is against the natural law. As a result, the electric field distribution of the driving area in the axis of the photodiode generates a hollow and lower distribution. Hence the depletion layer presents an annular distribution. Its uneven distribution lowers the performance of the photodiode and generates noises.

Nowadays worldwide copper resources decrease constantly, and optical fiber manufacturing technology has been developed more than twenty years. People have great demand of bandwidth. But the optical fiber still cannot fully take over the mission of communication medium. Many people still cannot fully enjoy the broadband benefit of Fiber-To-The-Home optical fiber services. There are still rooms for improvement.

Therefore it is an object of the invention to solve the aforesaid disadvantages of the traditional optical fiber technology.

In order to overcome the problems of the transitional optical fiber and light source and photodiode, the present invention provides three techniques coupled in one set to redefine the waveguide structure of optical fiber, and structures of semiconductor light source and semiconductor photodiode. They can be integrated into a coaxial light-guide system to provide comprehensive applications. The three techniques of the invention are discussed as follow:

1. Coaxial light guide optical fiber: It is an optical fiber with refractive index profile allocating on radii rather than on the diameter as the prior optical fiber does. The optical fiber includes both an annual core and a circular outer-cladding together with axial inter-cladding that are coaxial and have a same refractive index. The refractive index profile center which light guide depends is moved from the axis to the entire radii. And light propagates between the axial inter-cladding and the coaxial circular outer-cladding rather than through the axis. As the axial inter-cladding and outer-cladding have the same refractive index, optical wave is moved to the annular core formed by the middle portion of the entire radius to propagate as shown in FIGS. 8A and 8B rather than concentrates in the optical fiber core at the axis for propagating as the traditional approach does.

FIG. 8A illustrates a coaxial graded index multimode optical fiber which has an annular core 803 propagating in an optical self-focusing model. Light travels in a geometric path commonly known in a total reflection model through an axial cladding and an outer cladding of the same refractive index at the same radius. Namely the longitudinal plane on the radius across the optical fiber serves as the light guide plane to replace the traditional design which has the longitudinal plane on the diameter FIG. 8B illustrate a coaxial single-mode optical fiber 801 with an annular core 802 to propagate light. The optical fiber of the invention differs from the prior one, referring to FIGS. 9A, 9B and 9C. New terms are introduced. For instance, in FIG. 9A, a new annular layer structure is formed that has a main light guide area 901 called an annular core. It has a refractive index n₁. There are two portions with a lower refractive index to form total reflection at an outer side and an inner side. They are called an outer cladding 902 and an axial cladding 903, or an outer cladding and an inter-cladding. The inter-cladding has a refractive index shown by ᵢn₂. The outer cladding has a refractive index shown by ₒn₂. As the refractive indices are the same, namely i ᵢn₂=ₒn₂. But in some occasions in order to take into account of impact on optical wave propagation characteristics caused by the doped material in the annular core, or refractive index difference (Δ %) against loss of sensitivity caused by a slight bending or other factors such as preventing OH moisture from entering the core, two or more of claddings are formed. For instance, a matched cladding and a depressed cladding are provided to adjust the refractive index ratio difference. They are indicated by other symbols.

FIG. 9A illustrates a coaxial optical fiber of the invention for single-mode step index optical fiber, FIG. 9B illustrates a coaxial optical fiber of the invention for graded index multimode optical fiber, and FIG. 9C illustrates a coaxial optical fiber of the invention for step index multimode optical fiber. Each has its optical wave propagation method in the optical fiber.

2. Coaxial semiconductor light source: As the axial cladding of the coaxial optical fiber no more transmits light, and the annular core surrounds the axial cladding, the axis of light source is altered to become the center electrode to supply electric power. The coaxial conductor forms a coaxial semiconductor light source. Two positive and negative coaxial electrodes at the inner side and outer side supply electric power to the emitting annular semiconductor layer in the middle in a coaxial model. Hence the annular emitting element emits optical wave to the optical fiber of annular core in a desired model. The incident optical power loss occurred to the prior technique can be prevented. Thus the coaxial optical fiber of the invention can provide an optimal match in terms of energy shape.

The laser light source adopted the coaxial semiconductor structure is shown in FIG. 10A, where 1001 represents an axial positive electrode, 1002 is an outer annular negative electrode, 1003 is a n-type substrate, 1004 is a n-type semiconductor layer, 1005 is a p-type active layer, 1006 is a p-type semiconductor layer, 1007 is a reflective layer. FIG. 10A is a sectional view of the structure of the coaxial semiconductor annular layer laser of the invention (cutting off in half from the center, excepted FIG. 16). FIG. 10B is the basic structure of a traditional semiconductor laser fabricated through planar layer vertical distribution, where 1004 is a n-type semiconductor layer, 1005 is a p-type active layer, 1006 is a p-type semiconductor layer, 1007 is a reflective layer, 1008 is a positive electrode, 1009 is a negative electrode, and 1010 is laser output. According to the invention, each coaxial semiconductor light source can be arranged according to the annular light emission semiconductor and fabricated to emit light and injected as desired into a coaxial optical fiber. For instance, through a commonly known light generation principle such as a coaxial DFB distribution feedback semiconductor laser or coaxial semiconductor laser with adjustable wavelength, a desired light emitting function can be achieved.

3. Coaxial semiconductor photodiode: As the axial cladding in the center of the coaxial optical fiber no longer transmits light, and the optical wave emitted from the coaxial optical fiber is annular, the middle portion of the prior photodiode that receives light is no longer needed and could become the source of noise. The axis portion is where the electrodes located that supply electric power, thus forms the coaxial semiconductor photodiode through a coaxial conductor structure. Two positive and negative coaxial electrodes at the inner side and outer side supply electric power to the light receiving annular semiconductor layer in the middle in a coaxial model. Hence the optical fiber with the annual core fiber can receive the optical wave in a desired model. The incident optical power loss occurred to the prior technique can be prevented, and sensitivity improves. It also provides an optimal match for the coaxial optical fiber of the invention in terms of energy shape.

Refer to FIGS. 11A and 12A for the structures of a photo detection PIN diode and an avalanche APD photodiode, that are also the structure of the coaxial semiconductor photodiode of the invention. FIGS. 11B and 12B show the structure of the prior planar layer vertical distribution semiconductor photodiode. The coaxial semiconductor photodiode of the invention, by arranging the annular semiconductor layers which provides various light detection functions, can be made to provide required light detection function on the light emitted from the coaxial optical fiber. In FIG. 12A, the coaxial APD includes a conductive axial electrode 1101 which provides positive electricity and a coaxial outer annular conductor 1102 to provide negative electricity, and a plurality of coaxial annular semiconductor layers formed and jointly mounted onto a P—InP substrate 1106. In addition, 1103 is a n⁺ InP, 1202 is a p-InP multiplication layer, 1104 is an Intrinsic absorption layer made of n-InGaAs, 1105 is a P⁺—InP layer, 1107 is a reflective layer, and 1108 is an anti-reflection layer. In FIG. 11B, 1008 is a positive electrode, 1009 is a negative electrode, and 1109 is photon injection.

More details are discussed below.

1. The coaxial light guide optical fiber of the invention can solve the disadvantage 1 mentioned before. As the refractive index profile of deciding waveguide has repositioned on radii, optical wave energy that would otherwise be concentrated to pass through the center of the refractive index profile is shifted to the middle portion of the entire radii. Fabrication of the preform tube adopts inside deposition process such as MCVD and PCVD. Based on the refractive index at the outmost outer cladding blending of doped materials are started accordingly. As the refractive index gradually increases from the outer layer to the inner layer, deposition is arranged accordingly and the thickness increases gradually towards the inner layer. After having finished deposition of the highest refractive index layer of the refractive index profile center, deposition of the lower refractive index layer is gradually formed. Finally a plurality of pure silicon deposition layers with the refractive index same as the outer cladding quartz tube of pure silicon are formed. A transparent preform tube thus formed can go through the collapse process.

Refer to FIGS. 13A and 13B for examples of deposition of graded index multimode preform. FIG. 31A illustrates refractive index profile on a cross section of a preform tube after deposition has finished before collapsed to form a solid core, with deposition sequence starting from A₁ to An, 130 is a quartz tube, 131 is refractive index profile, 132 is refractive index profile without depressed in the center, and 133 is the hollow portion of the preform tube. FIG. 13B illustrates the refractive index profile on a cross section of a preform tube after collapsed to form a solid core. The optical fiber of the invention has a waveguide plane formed by a longitudinal plane on the radius. The refractive indices at the axis and outer cladding are the same. The doped deposition layer with a higher refractive index is moved to the middle portion in entire radii. Hence the doped material of the higher refractive index is less likely to evaporate during collapse process at high temperature. Similarly, when OVD method is adopted, forming the pure silicon of the same refractive indices at the axis and outer cladding by deposition starts from the inner layer to the outer layer (the sequence is inverse to MCVD and PCVD methods, namely from Aₙ to A₁). After the final deposition step is finished, dehydration at high temperature and Sintering processes are proceeded. According to the invention, the refractive indices at the axis and the outer cladding are the same, and the doped deposition layer with a higher refractive index is moved to the middle portion in entire radii, hence the doped material of the higher refractive index is less likely to evaporate during processes at high temperature. As the optical fiber of the invention has the waveguide plane formed by the longitudinal plane on the radius across the coaxial optical fiber, the problem of center-dip in the refractive index profile does not take place when it is fabricated through the methods of MCVD, PCVD and OVD. All these three methods can be adopted as desired.

2. The coaxial light guide optical fiber of the invention can solve the disadvantage 2 mentioned before. With the light guide refractive index profile repositioned on the radii in the coaxial optical fiber according to the invention, the transparent preform tube formed by deposition as previously discussed can go through quality control in advance and fiber can be drawn directly. After deposition has finished, the refractive index at the intended core portion of the hollow tube is same as the outer cladding. Before collapse to form a preform of a solid core, the inner and outer layers of the preform tube are formed by the same material. It can be moved to an ordinary environment to do quality control and inspect refractive index profile without contaminating the inner tube. After quality control is finished fiber drawing can be performed directly to save the cost of collapse process. Although the preform tube made through MCVD and PCVD at this stage still has a rather large hollow inner diameter, but the core portion of light guide has hundreds pure silicon layers without doped Germanium, it is far away from the possible contamination in the manufacturing process. The internal and external stress difference also is more evenly formed and balanced because of symmetrically distribution of material at the inner and outer side. Crack caused by a great stress difference also can be eliminated.

3. The coaxial light guide optical fiber of the invention can solve the disadvantage 3 mentioned before. In order to reduce transmission loss communication optical fiber often is made from very pure and expansive materials, including high precision and expensive equipments. The products being fabricated also are expensive. Hence to effectively use waveguide material in the optical fiber to increase optical flux to transmit more energy is an issue worth to be addressed seriously. The effective optical flux A of a unit area of optical fiber, also called effective optical flux ratio, can be defined as follow:

A=A_{w}/A_{f}×100% (1)

where A_{f} is the cross section area of the optical fiber, A_{w} is the cross section area of the light guide in the optical fiber. Referring to FIGS. 14A and 14B, given a single-mode optical fiber 1401 at a same outer diameter 125 μm, FIG. 14A shows a traditional single-mode optical fiber with a light guide core 1403 at a diameter of 10 μm, the effective optical flux ratio is A_{T}. FIG. 14B shows a single-mode coaxial glass optical fiber 1402 according to the invention, with an annular slab waveguide structure at 10 μm and a thickness 2t the same as the cutoff wavelength, t can be derived by the following equation:

$$\begin{matrix}λ c = 4 t \times {( {n}_{1}^{2} - {}_{i}^{}{n}{}_{2}^{2} )}^{0.5} & ( 2 ) \\ = ( 2 π / 2.405 ) \times a \times {( {n}_{1}^{2} - {}_{i}^{}{n}{}_{2}^{2} )}^{0.5} & ( 3 )\end{matrix}$$

where equation (2) is calculated based on a slab waveguide path theory, while equation (3) is calculated based on cylindrical waveguide path theory. The thickness 1404 of the waveguide layer 1404 of the slab layer of the coaxial single-mode optical fiber t=0.653a=0.653×5=3.3, namely the slab layer has a thickness 2t=6.6 μm.

Compared with the effective optical flux ratio AN, based on equation (1), the followings can be derived:

A_{T}=π×5²/π×62.5²×100%=0.64%

A_{N}=π×(34.55²−27.95²)/π×62.52×100%=10.56%

A_{N}/A_{T}=10.56/0.64=16.5 times.

Compared the two set forth above, given a single-mode optical fiber of the same outer diameter, the coaxial optical fiber of the invention has an effective optical flux ratio 16.5 times of the traditional optical fiber. Namely the utilization efficiency of the effective light guide material improves by 16.5 times. For the same area that originally aims to support the optical fiber and connection, the optical flux increases accordingly. Not only utilization of the effective light guide material increases 16.5 times, the single-mode optical fiber also provides more energy to the receiving end, and the receiving end can be moved farther away and still get the same sensitivity to increase communication distance.

4. The coaxial light guide optical fiber of the invention can solve the disadvantage 4 mentioned before. With the light guide coaxial optical fiber of the invention repositioning the refractive index profile on the radius, the light guide area of the single-mode optical fiber is expanded from the prior small circular core to the annular ring area in the middle portion of the entire radii. The light guide area increases by 16.5 times, and the effective optical flux ratio also increases by 16.5 time. Hence the prior problem of small core can be resolved. Based on the example previously discussed, the inner light guide cross section area A_{w} of the prior single-mode optical fiber and that of the invention can be calculated as follow:

for the prior single-mode optical fiber, A_{w}=5²π=25 πμm²,

for the invention, A_{w}=(34.55²−27.95²)π=412.5 πμm²

Thus the difference of the light guide area of the two is 412.5/25=16.5 times.

As the optical flux is proportional to the light guide area, the light guide area of the coaxial single-mode optical fiber of the invention increases by 16.5 times, that also means increases energy supply in the single-mode optical fiber by 16.5 times. With the single-mode slab waveguide structure able to transmit 16.5 times of optical energy, given a photodiode at the receiving end with a same sensitivity, the laser power and cost of the light source can be reduced greatly. Or for a given light source of the same laser power, communication distance can be increased.

Set P₀ to be optical power input to a light detection diode, Np is the photon number injected into the photodiode in an unit time, ν is light frequency, and h is the Planck's constant, then the following equation can be provided:

Po=Np×hν

Assumed optical power P₀ (1) is sent to a photodiode of a prior single-mode, and Po(2) is the optical power of the single-mode of the invention sent to the photodiode, the following equations can be derived:

Po(1)=Np×hν

Po(2)=16.5Np×hν

Hence the optical flux of the single-mode optical fiber of the invention is 16.5 times of the prior one, and 16.5 times of photons can be transmitted. For a given photodiode, 16.5 times (Po(2)/Po(1)=16.5 )of optical power can be received. Hence light intensity can be increased by 10×log 16.5=12 dB. Given a photodiode of the same sensitivity and a laser light source of the same power, adopted the single-mode optical fiber of the invention transmission loss is 0.4 db/Km at 1300 nm zero dispersion wavelength, and the distance can be increased by 12/0.4=30 Km. Hence with the single-mode optical fiber of the invention being able to carry 16.5 times of photons by transmitting the zero dispersion wavelength, the photodiode of the same sensitivity can detect a minimum photon receiving quantity at an increased distance of 30 Km. Given a photodiode of the same sensitivity, the power and cost of laser light source can be greatly reduced. Or the laser light source of the same power can support a much longer communication distance.

5. The coaxial semiconductor light source injecting into the coaxial optical fiber can solve the disadvantage 5 mentioned before. The coaxial optical fiber of the invention, by having the refractive index profile on the radius, has the optical fiber light guide structure changed to allow an annular ring formed in a light guide section on the entire radii to transmit light. Namely the annular core transmits light, while the inter-cladding at the axis no longer transmits light. As the coaxial semiconductor light source of the invention also has an axial electrode which does not emit light. Instead, an emitting annular semiconductor layer emits annular light to enter the annular core of the coaxial optical fiber. Thus an annular against annular mating is formed to comply with the natural law(principle). The problem of power loss caused by non-mating shape is overcome. The problem of polarization mode dispersion (PMD) also is reduced. As the two coaxial electrodes that supply power have the annular semiconductors facing each other to generate electrons and electric holes that flow in the shortest distance, it coincides with the polarized direction of the radius. Namely, in a formed maximum radial electric field, carriers and stimulated photons are moved in the driving direction of the maximum radial electric field. Hence the laser of a coherent optical wave stimulated and generated by a resonant cavity of one frequency or a selected frequency produced by the coaxial semiconductor layer of the invention, the polarized and radiated direction of the stimulated light is attracted by the strongest electric field of the radius polarized direction generated by the coaxial power supply of the invention, and emission waves radiated according to radius polarization are formed. Such radius polarization waves are like the only vertical polarization waves with the horizontal polarization being zero. Hence the problem of polarization mode dispersion is smaller. With the coaxial semiconductor laser of the invention to generate a annular laser of zero dispersion at 1300 nm in single frequency coherent and radius polarization to be injected in the annular core of the coaxial single-mode optical fiber of the invention, the radius polarized light is like entering the radius longitudinal wave guided optical fiber with propagation taking place on each radius longitudinal plane. Thus optical fiber communication of a greater bandwidth and longer distance can be realized. The coaxial semiconductor light source of the invention can mate snugly the annular core light guide structure of the coaxial optical fiber of the invention, as shown in FIGS. 15A and 15B.

6. The coaxial semiconductor photodiode of the invention can solve the disadvantage 6 mentioned before. As the coaxial semiconductor photodiode of the invention has two coaxial electrodes to supply electric power, and the annular rings of the coaxial semiconductor around the center electrode have a same thickness, electrons and electric holes travel by the shortest path along the radius to the outer annular electrode. And electric field distribution direction of the annular depletion layer formed by the inverse bias voltage power supply or the multiplication layer or absorption layer of the avalanche diode is distributed in the radius polarized direction. Viewing based on the cross section, the annular depletion layer mates snugly the annular optical wave output from the coaxial optical fiber, hence an optimal power coupling light detection can be achieved. Although the prior photodiode also can receive the optical wave energy distribution shape emitted from the optical wave annular ring of the optical fiber of the invention, to accomplish the optimal match of energy shape, each emitted photon should be given a maximum receiving effectiveness so that optimum coupling efficiency can be achieved to fully provide light detection function. Hence choosing the coaxial semiconductor photodiode of the invention is the most desirable approach to comply with the natural law, as shown in FIGS, 15B and 15C. In addition, as the depletion layer which aims to detect light directly receives photo electric current generated by electron and electric hole pairs upon receiving light that becomes drift current, but not diffusion current, thus response speed is faster, and communication distance can be increased.

As a conclusion, the invention, after repositions the light guide refractive index profile on the radius in the optical fiber, can eliminate the disadvantages of the prior optical fiber that has the refractive index profile done on the diameter. The shortcomings occurred to the light source and photodiode of the prior techniques also are overcome. In addition, the invention also can accomplish the following objects:

1. The problem of center-dip in the refractive index profile occurred by adopting the MCVD, PCVD and OVD methods are eliminated, and various types of high quality optical fibers with desired refractive index profile can be fabricated by employing the MCVD, PCVD and OVD methods to enable light to propagate in the optical fiber according to a selected path.

2. The preform tube formed by inside deposition can go through quality control process in advance and fibers can be drawn, thus the cost of collapse process can be saved and transmission loss can be reduced. Bandwidth also increases. By omitting collapse process of the preform tube a great amount of energy can be saved. Coupled with direct fiber drawing, contamination of water molecules during the traditional hours of collapse process can be prevented. Moreover, during collapsing performed horizontally on a glass lathe the preform often is deformed due to alignment problem of chucks at two sides of the lathe and dislocation at high temperature and spinning operation. Such deformation caused by operation often reduces the genuine circularity of the internal structure of the solid preform and increases the concentricity of the core. This impairs transmission characteristics and affects quality. The coaxial optical fiber of the invention has the preform tube going through quality control and fibers can be drawn directly and by means of vertical machines, energy waste occurred to solidifying the core of the preform is reduced. Manufacturing time is shorter and the required investment on horizontal collapsing machinery is less. Moreover, the light guide core is not contaminated. Hence high quality products can be obtained.

3. Optical wave energy that mainly concentrates to pass through the refractive index profile center is moved to the middle portion of the entire radii, and the single-mode optical fiber has the effective optical flux ratio increased by 16.5 times, utilization of the expensive semiconductor material also is higher, thus manufacturing cost is lower.

4. By moving the refractive index profile center that the optical wave main energy passing from prior axial tiny core to the middle portion of entire the radii, total optical flux increases by 16.5 times. Such an approach combines the double advantages of both the traditional single-mode optical fiber and multimode optical fiber. The invention, not only can reduce connection loss, also does not need to adopt the graded index multimode optical fiber which is more complex and expensive to fabricate. The optical fiber of the invention can be fabricated simpler and mate snugly the light source and photodiode to achieve optimal power utilization. In addition, a single-mode optical fiber made from silicon can be selected to 5obtain zero dispersion at wavelength 1300 nm. All the desirable factors set forth can be combined to increase communication distance or reduce the costs of light source and operation so that more applications of optical communication can be developed and adopted, especially Fiber-To-The-Home broadband applications. This ultimately contributes smoother flow of information and knowledge sharing for mankind.

5. The coaxial optical fiber, coaxial light source and coaxial photodiode of the invention can be coupled to form a desired integrated combination. A novel coaxial light guide system is created. It makes utilization of light guide materials more effective. The valuable laser energy can be more efficiently deployed to transmit rare photons to be detected at a farther remote end.

6. Extend the coaxial century. The coaxial cable has made a great contribution to the wellbeing of mankind for a century. In the last twenty years, it is proved that the prior optical fiber light guide system has many benefits, such as resist electromagnetic interference, lower loss and greater bandwidth and the like. Hence it gradually replaces the high frequency coaxial cable used in the prior electronic communication. But the coaxial characteristics have many advantages remained undiminished. The invention, by combining the coaxial optical fiber, coaxial light source and coaxial photodiode into one system such as the embodiment 2 discussed below, can be adopted and adapted in other embodiments and applications to maximize its benefits. Through the invention electromagnetic wave is elevated to a pure and clean optical wave usable by mankind continuously. And the knowledge and intelligence accumulated by people in the past can be enjoyed by more people and more generations to come.

Because the light guide refractive index profile is changed to the radius, the present invention can achieve the foresaid objects and also resolve many problems occurred to optical fiber communications in the past. By repositioning of the invention, many of the aforesaid problems occurred to the prior techniques are eliminated. The prior problems of high cost and waste of materials and resources are resolved because of the change of the light guide refractive index profile on the radius. As a novel optical fiber manufacturing technique and communication method are provided by the invention, the complicated and costly conventional manufacturing methods can be abandoned. Adopted the invention, the applications of optical fiber can be spread more widely such as Fiber-To-The-Home optical fiber services. And the new generation of single-mode optical fiber and a lower power coaxial laser can be used to fully exploit the advantages of zero dispersion wavelength to boost bandwidth, and more economic benefits can be reaped. Through the invention, repositioning of optical fiber becomes possible, and knowledge sharing is easier to materialize. It ultimately can make a great contribution to the wellbeing of mankind.

The foregoing, as well as additional objects, features and advantages of the invention will be more readily apparent from the following embodiments and description, which proceed with reference to the accompanying drawings.

### BRIEF DESCRIPTION OF THE DRAWINGS

FIG. 1 is a schematic cross section of a prior optical fiber.

FIGS. 2A, 2B and 2C are schematic views of the structures of various types of prior optical fibers and the waveguides thereof.

FIG. 3A is a schematic view of the structure of a flexible thin film waveguide.

FIG. 3B is a schematic view of the slab waveguide according to U.S. Pat. No. 3,659,916.

FIG. 4A is a schematic view of center-dip in the refractive index profile of a single-mode optical fiber.

FIG. 4B is a schematic view of center-dip of graded index fiber.

FIG. 5 is a schematic view of an edge-emitting laser and an elliptic light output radiation waveform.

FIG. 6 is a fragmentary sectional view of a conventional Vertical Cavity Surface Emitting Laser (VCSEL) light source with an surface ring electrode.

FIG. 7 is a schematic view of a prior front illuminated photodiode with an ring electrode and electric field distribution of the depletion region thereof.

FIG. 8A is a fragmentary schematic view of the structure of a graded index multimode optical fiber of the coaxial optical fiber of the invention and optical wave propagation approach in the optical fiber.

FIG. 8B is a fragmentary schematic view of the structure of the coaxial single-mode optical fiber of the invention and optical wave propagation approach in the optical fiber.

FIG. 9A is a schematic view of the structure of the coaxial step-index single-mode optical fiber of the invention and optical wave propagation approach in the optical fiber.

FIG. 9B is a schematic view of the structure of the coaxial graded index multimode optical fiber of the invention and optical wave propagation approach in the optical fiber.

FIG. 9C is a schematic view of the structure of the coaxial step-index multimode optical fiber of the invention and optical wave propagation approach in the optical fiber.

FIG. 10A is a fragmentary sectional view of the structure of a coaxial semiconductor annular layer laser of the invention.

FIG. 10B is a schematic view of the basic structure of a prior semiconductor laser formed in planar layer vertical distribution construction.

FIG. 11A is a fragmentary sectional view of the structure of a coaxial semiconductor light detection PIN diode and a sectional view of the coaxial semiconductor PIN photodiode of the invention.

FIG. 11B is a schematic view of the structure of a prior semiconductor PIN photodiode in planar layer vertical distribution construction.

FIG. 12A is a fragmentary sectional view of the structure of a coaxial avalanche APD photodiode and the coaxial semiconductor photodiode of the invention.

FIG. 12B is a schematic view of the structure of a prior avalanche APD photodiode in planar layer vertical distribution construction.

FIG. 13A is a schematic view of refractive index profile on a cross section of a preform tube after deposition is finished before collapsed to form a solid core, with deposition sequence from A₁ to Aₙ.

FIG. 13B is a schematic view of refractive index profile on a cross section of a preform tube after collapsed to form a solid core.

FIG. 14A is a schematic view of a single-mode optical fiber with an outer diameter of 125 μm and a core at a diameter of 9 μm calculated according to effective optical flux.

FIG. 14B is a schematic view of a coaxial glass single-mode optical fiber of the invention with a thin film formed at a thickness 7 μm in the condition of same cutoff wavelength.

FIG. 15 is a fragmentary sectional view of an embodiment of a coaxial light guide system consisting of a coaxial optical fiber, a coaxial light source and a coaxial photodiode in cooperating with a receiving and transmission end.

FIG. 16 is a fragmentary sectional view of embodiment 2 of a coaxial light guide system that has a coaxial semiconductor transceiver coaxially mounted onto a same substrate to share the only coaxial optical fiber to save another optical fiber.

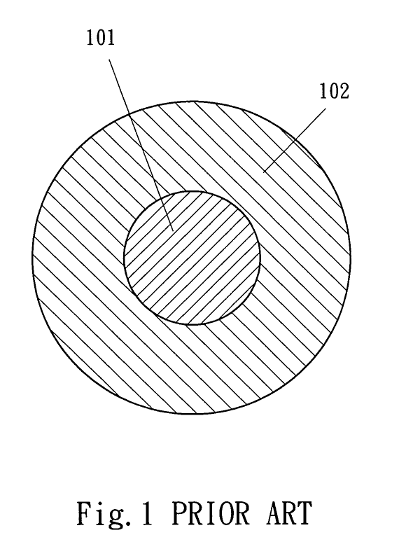

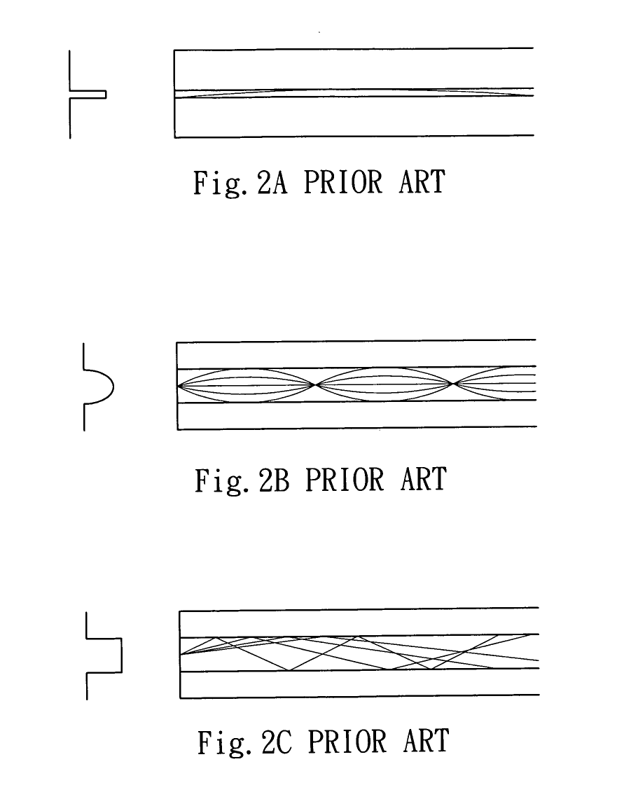

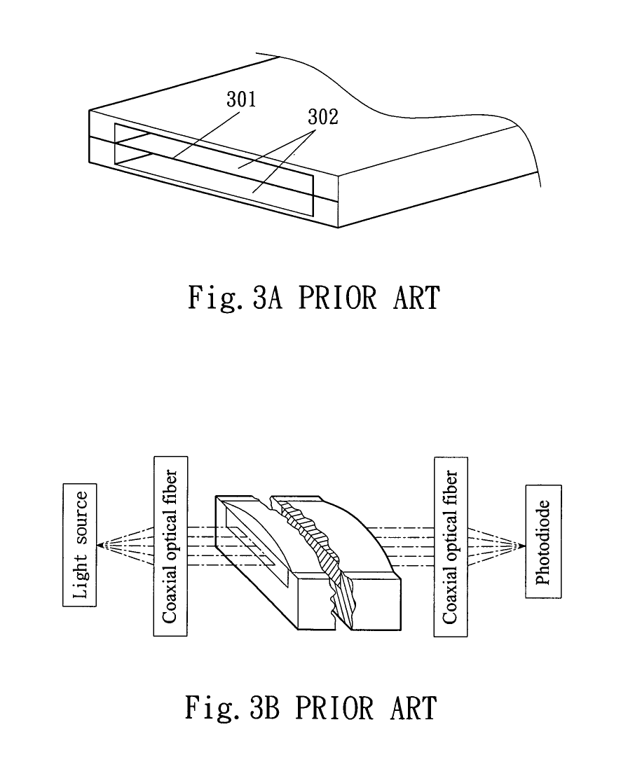

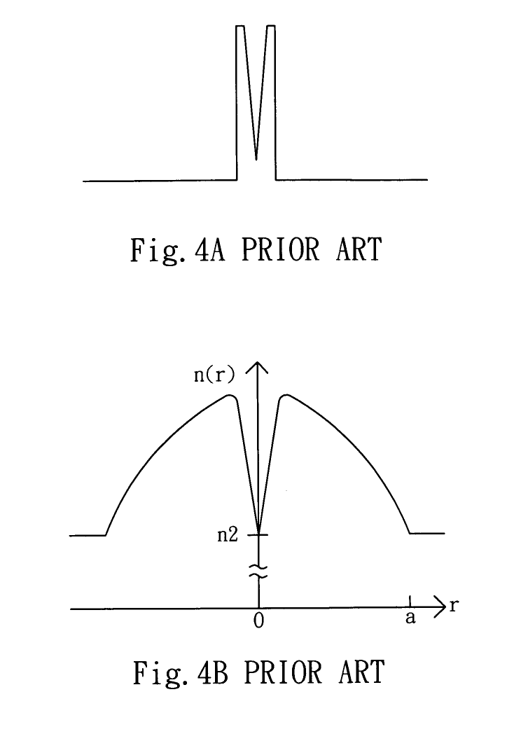

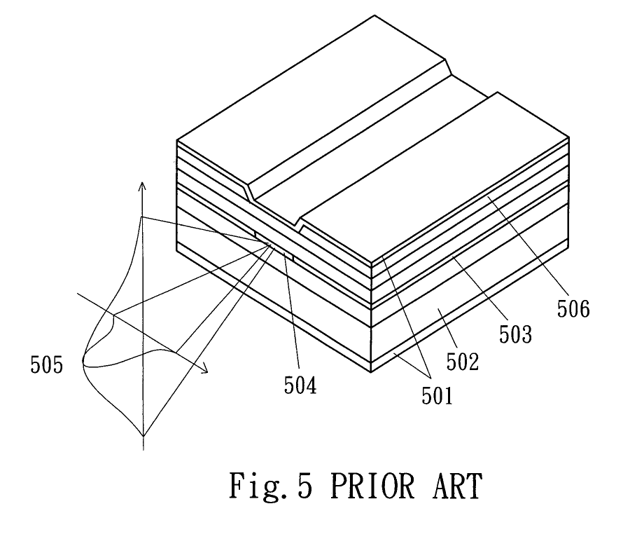

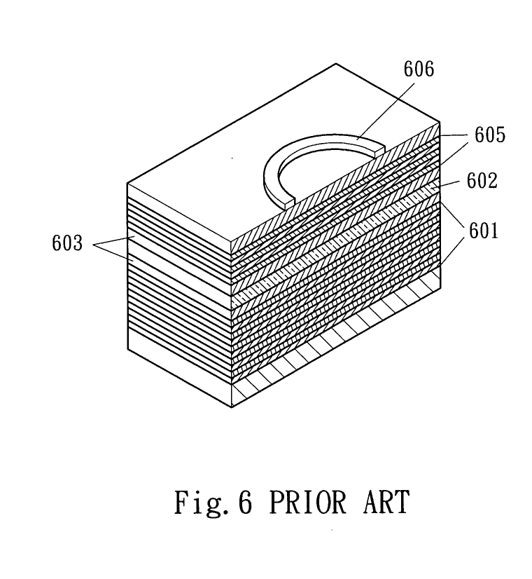

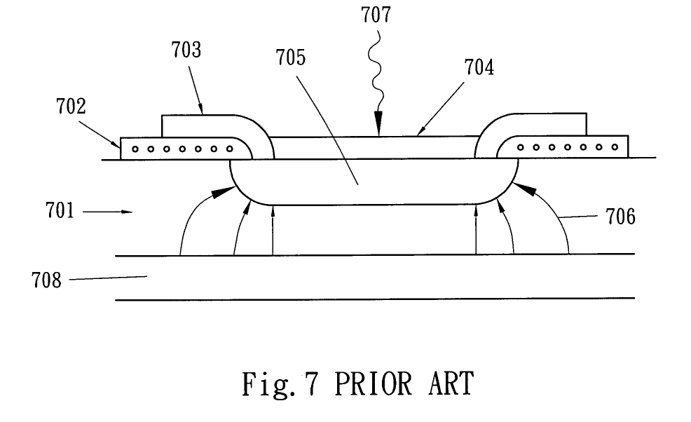

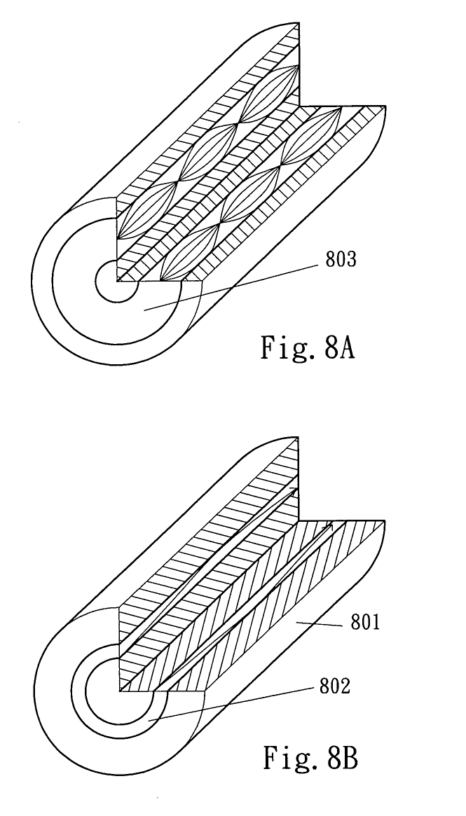

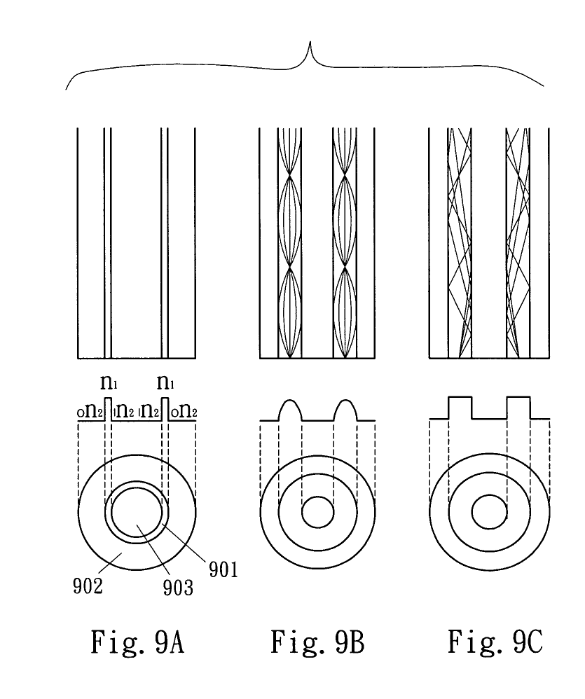

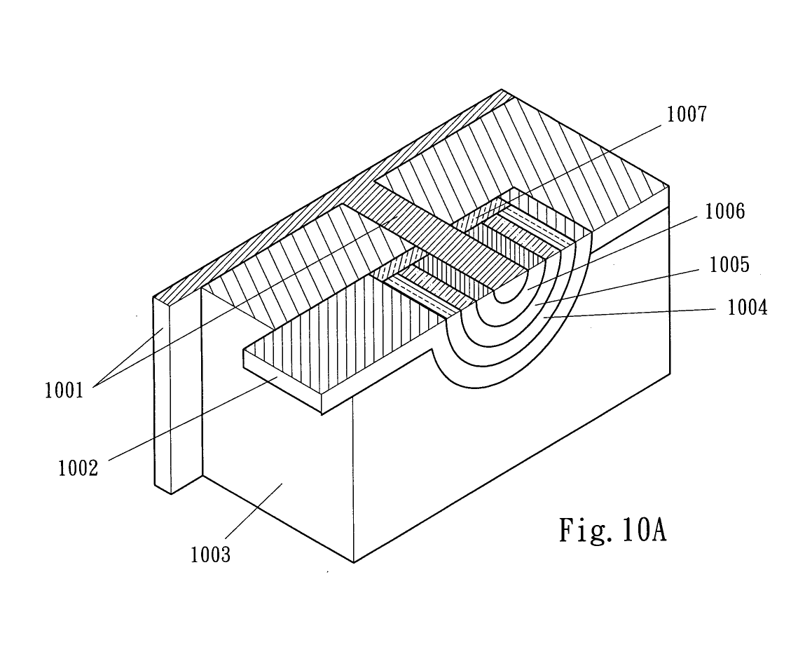

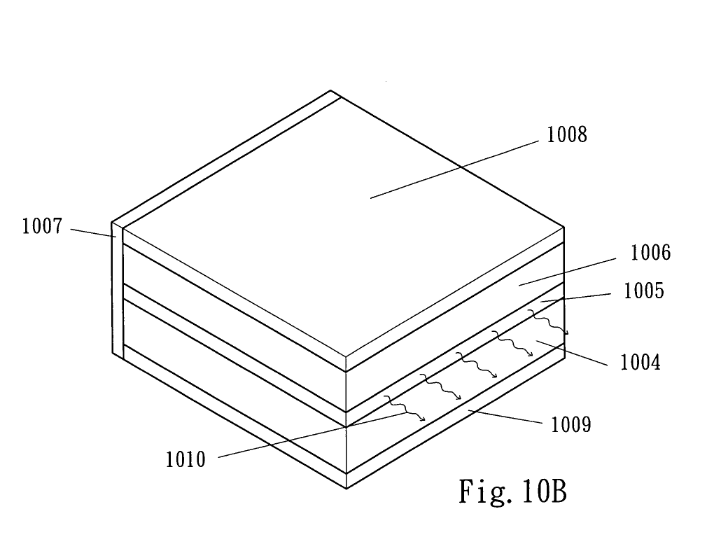

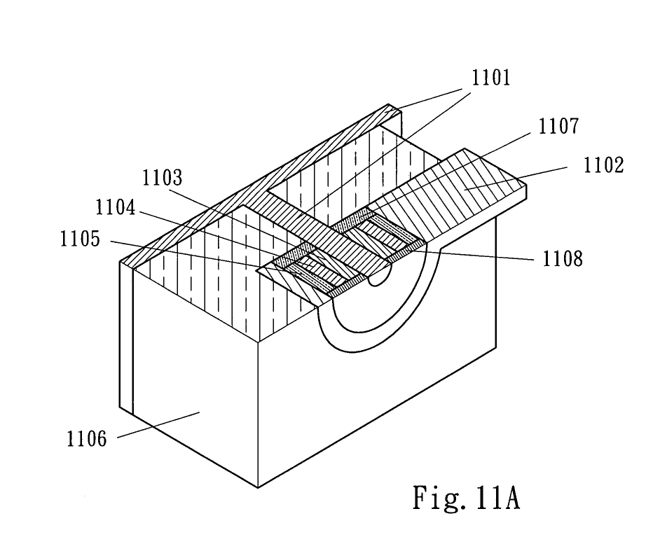

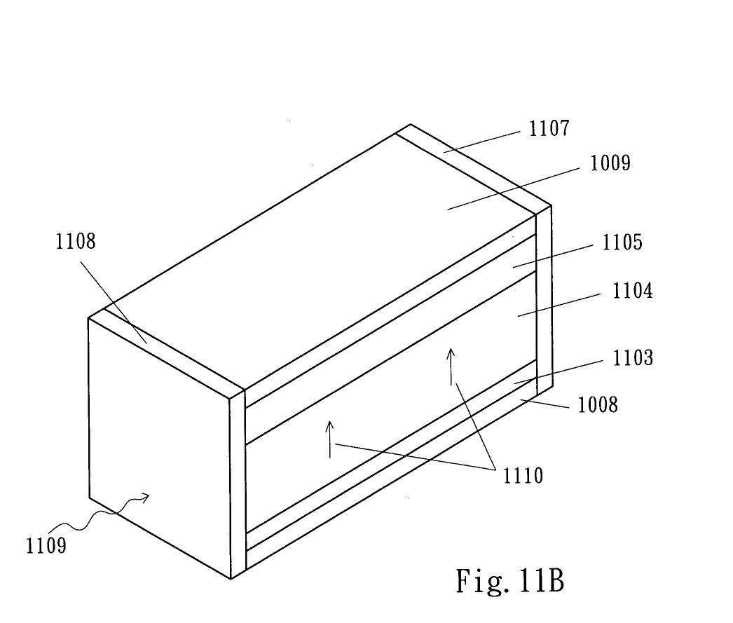

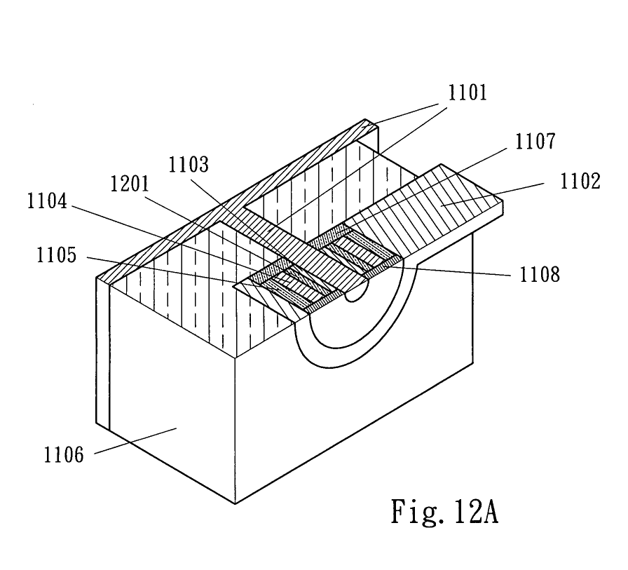

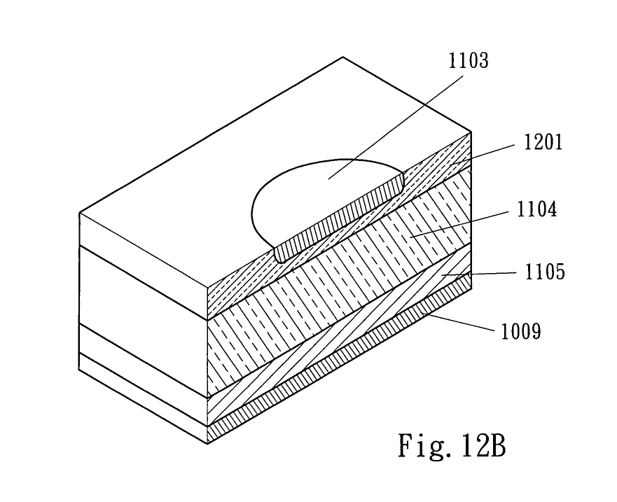

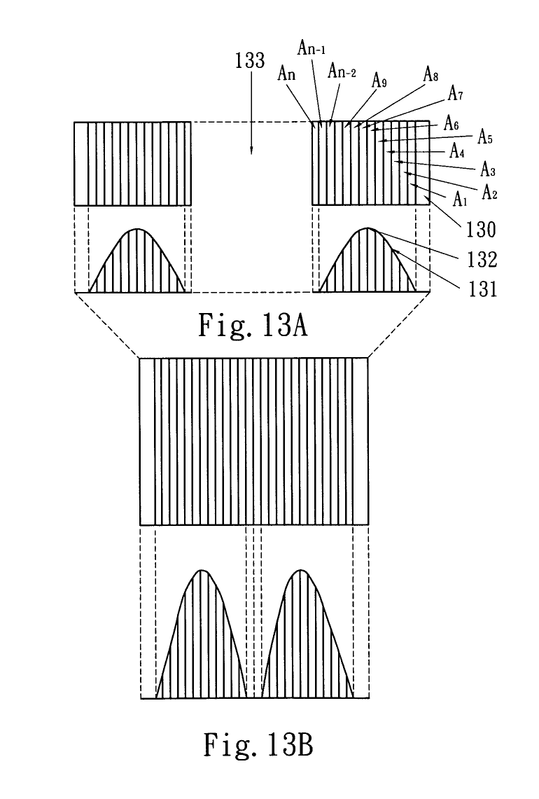

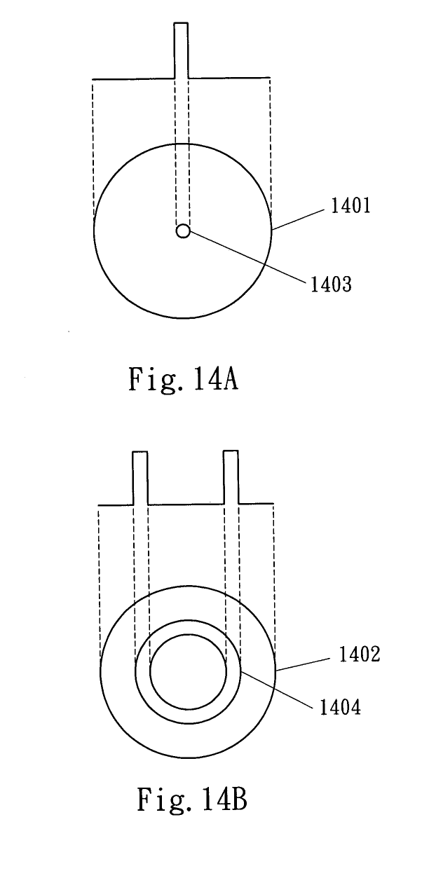

### DETAILED DESCRIPTION OF THE PREFERRED EMBODIMENTS

### Embodiment 1

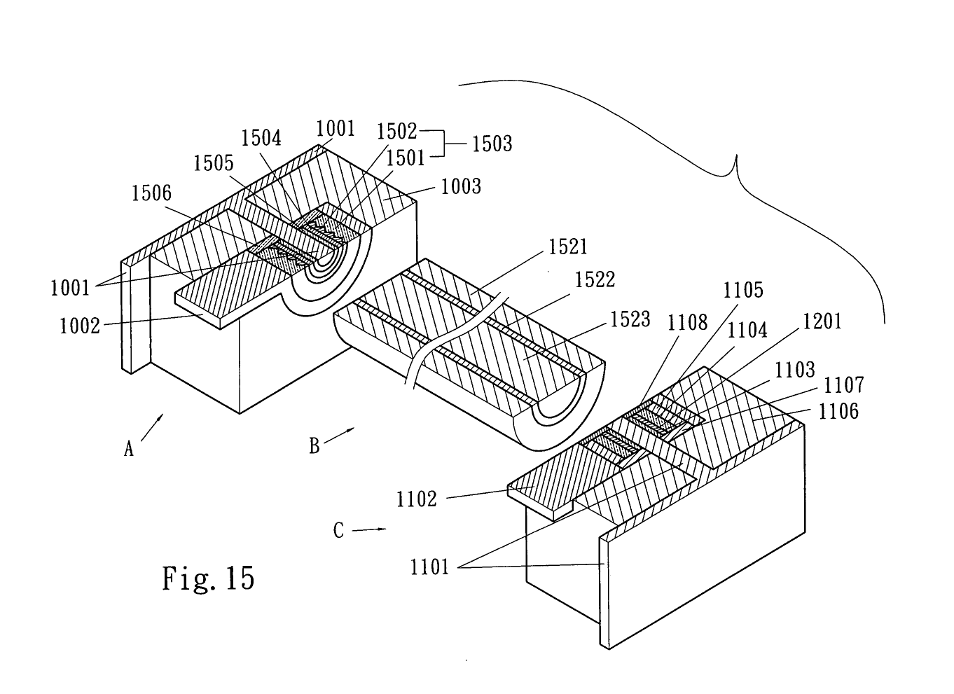

An optical fiber system consisting of a coaxial optical fiber, a coaxial light source and a coaxial photodiode that is coupled with a transceiver end is illustrated in FIG. 15. The numerals that are same as the ones of previous discussion are deemed to provide same or similar functions. The drawings are merely a simplified means to elaborate the features of the invention, and do not intend to cover all the details of actual practice nor present by actual dimensional scale. However they reflect the basic coaxial light guide principle the invention adopts.

In FIG. 15 the light source A is a coaxial semiconductor laser. It is a coaxial DFB heterostructure Distributed Feedback Bragg's laser diode shown in a fragmentary sectional view. Its structure adopts a prior planar DFB heterostructure Distributed Feedback Bragg's laser diode to coincide with natural law which the present invention intends to establish. More specifically, the DFB heterostructure laser includes a conductive axis electrode 1001 to provide positive electricity and an axial outer ring conductor 1002 to provide negative electricity, with multiple layers of coaxial annular semiconductor located between them that are jointly mounted onto a n-InP substrate 1003. The multiple layers of coaxial annular semiconductor may be formed in homo junction, or isotype heterojunction, or unisotype heterojunction to emit light spontaneously or by stimulated. The light emission, like a prior technique, can adopt feedback function of Bragg's grating to become a distributed feedback laser diode. The coaxial semiconductor light source of the invention adopts the coaxial principle. In this embodiment the coaxial semiconductor light source adopts the coaxial heterojunction distributed feedback laser diode as an example for discussion. 1504 represents an annular active layer, 1505 is an annular semiconductor layer, 1503 is a Bragg's feedback grating and consists of 1501 n-InP annular semiconductor and a 1502 n-InGaAsP annular semiconductor. The Bragg's grating has a feedback wavelength λ_{B}, where λ_{B}=2 nΛ/m, and n is the refractive index of the semiconductor material, A is the period length of the Bragg's grating, m is 1 or 2 (called order of diffraction, usually is 1).

Optical fiber B in FIG. 15 is a coaxial light guide single-mode optical fiber, with an outer diameter 128 μm as an example for discussion. The thickness at the annular portion of the single-mode planar light guide is 2a=7 μm. The refractive index of annual core n₁=1.4629. The refractive index of intercladding ᵢn₂ equals to that of the outer cladding ₒn₂. Namely ᵢn₂=ₒn₂=1.46. Operation wave length λₒ=1.3 μm. According to the theory of planar light guide path, the slab propagation mode number N at thickness 2a is:

N=4a/λₒ×(n₁²−ᵢn₂²)^{0.5}=0.99≦1

When N≦1, it becomes a coaxial single-mode optical fiber, with a cutoff wavelength λ_{c}:

λ_{c}=4a×(n₁²−ᵢn₂²)^{0.5}=1.289 μm

The annular planar waveguide structure at the thickness 7 μm can make the single-mode optical wave injected from the coaxial semiconductor laser to be transmitted in a single-mode waveguide model with a glass zero dispersion wavelength 1.3 μm in the coaxial optical fiber to a coaxial semiconductor photodiode at a remote end, such as the optical fiber B shown in FIG. 15.

The photodiode C in FIG. 15 is a coaxial APD diode shown in a sectional view. Such a structure adopts an innovative design based on the prior planar semiconductor APD to coincide with the natural law in coaxial structure established in the invention. More specifically, the coaxial APD includes a conductive axis electrode 1101 to provide positive electricity and a coaxial outer ring conductor 1102 to provide negative electricity, with multiple layers of coaxial annular semiconductor located between them and jointly mounted onto a p⁺-InP substrate 1106. 1103 is n⁺ InP, 1201 is a p-InP multiplication layer, 1104 is an annular intrinsic semiconductor absorption layer n-InGaAs, 1105 is a P⁺—InP annular semiconductor layer, 1107 is a reflective layer, and 1108 is an anti-reflection layer. The prior planar layer vertical distributed structure avalanche photo diodes have many types. The coaxial avalanche photodiode depicted in the invention merely aims to represent the coaxial semiconductor photodiode of the invention to be coincided with the coaxial structure principle. Other types of photodiodes that can provide equivalent function of coaxial annular semiconductor light detection may also be adopted.

In the embodiment set forth above, the outer diameter of 128 μm for the single-mode optical fiber is larger than the prior 125 μm. It is chosen because it is an exponential times of 2 (namely 2², 2³, 2⁴, 2⁵, 2⁶, 2⁷=128). Calculation is easier. Such a number divided by 2 becomes an integer. It is more scientific than the prior number of 125, and the difference is not significant. The resulting radius is more than 1.5 μm. In this embodiment the coaxial single-mode optical fiber of the invention has an optical flux area larger than 22 times of the prior one, and has about 72% of optical flux area of the prior multimode optical fiber at the diameter of 50 μm, but the invention is much easier to make connection. This is an advantage of the invention.

The coaxial optical flux area Aw=(35.5²−28.5²)π=448π

The optical flux area of a traditional single-mode optical fiber at diameter 9 μm=4.5²π=20.25π

The optical flux area of a traditional multimode optical fiber at diameter 50 μm=25²π=625π

Thus the single-mode optical fiber of the invention not only has the advantages of the multimode optical fiber such as easier to operate and couplable with a lower power transceiver to reduce cost, also maintains the characteristics of single-mode fiber such as higher bandwidth. Thus it is a great improvement over the prior multi-mode optical fiber which has bandwidth capacity less than one mile. Through the invention, the complicated issues and bottleneck of the prior optical communication can be eliminated, and broadband optical communication can be realized at a lower cost.

### Embodiment 2

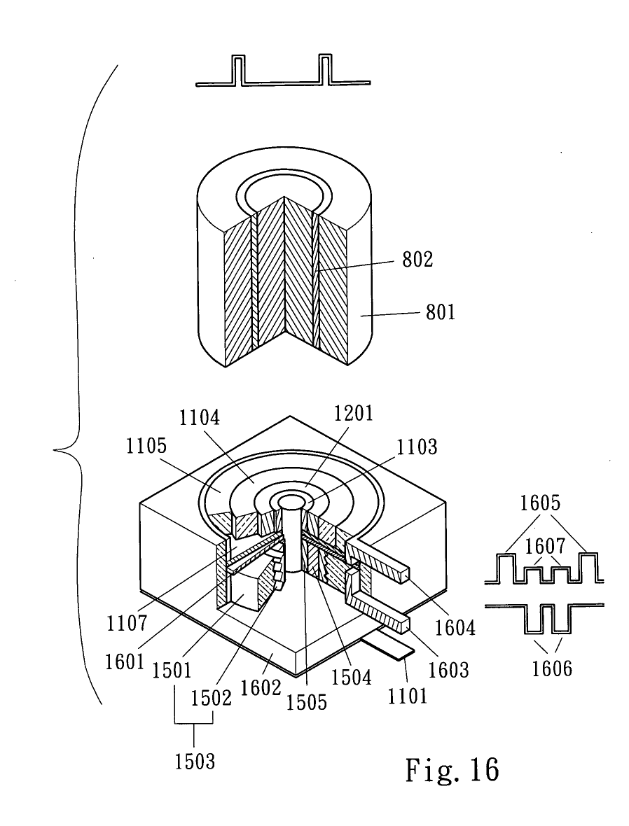

Refer to FIG. 16 for a second embodiment of the coaxial light guide system. It is an application example co-constructed with a coaxial semiconductor transceiver on a same substrate 1602 to share a single coaxial optical fiber 801 to save another optical fiber. The prior transceiver of optical fiber has the light emitter and the photodiode which receive optical signals fabricated separately, then coupled together. As the optical fiber can transmit optical wave in both directions, in the invention with the coaxial semiconductor light transceiver co-constructed on the same substrate a lot of hardware cost can be saved. Because all of three coaxial structures are co-constructed, they can be easy stacked in an up and down manner to form various types of combinations for different applications. The transceiver has an APD photodiode at an upper layer, 1103 is a n⁺ semiconductor layer, 1202 is a p-type multiplication layer, 1104 is an InP intrinsic semiconductor, 1105 is a p-type semiconductor layer, 1107 is a reflective layer, 1601 is an insulation layer with a partial reflector at a lower end, 1604 is an upper layer photodiode annular conductor. The lower layer is a DFB laser, 1603 is a lower layer coaxial outer annular conductor, 1501-1505 are light source elements like embodiment 1, 1101 is an axis positive electrode shared by the transceiver. The drawing on the right side in embodiment 2 provides electric power sequence to determine transmission and receiving conditions of optical fiber users. 1605 indicates that the upper APD photodiode provides high voltage power when the laser is not in operation so that an inverse bias voltage is provided to impact photo detection and generate current multiplication to be used for light detection. When the optical fiber user transmits signals, the lower DFB laser emits high voltage electricity 1606 to generate a single frequency optical wave. Meanwhile the upper layer photodiode supplies power 1607 at a lower voltage. As InP energy gap is greater than the photon, it is transparent against the light at the inverse lower bias voltage. Hence a great amount of optical power can pass to the annular core 802 of the coaxial optical fiber. Meanwhile, a little current generated by receiving photons can serve as a feedback power of the laser emission power for monitoring purpose. The coaxial optical transceiver thus constructed can save a great amount of network cost and one half of optical fiber transmission and receiving cost.

It is to be understood that in the embodiments depicted previously the functions and the coaxial light guide functions of each element, or two or more elements can be independently or jointly applied to the coaxial co-construct light guide and optical systems previously discussed or other types of optical and communication systems of the nature.

While the discussion, drawings and preferred embodiments of the invention have been set forth for the purpose of disclosure, they are not the limitation of the invention. Modifications of the disclosed embodiments of the invention as well as other embodiments thereof may occur to those skilled in the art. The principle and techniques may also be adapted to other applications, such as coaxial color image display devices, coaxial solid state illumination devices, coaxial color image detection devices, coaxial solar cells and the like. Accordingly, the appended claims are intended to cover all embodiments which do not depart from the spirit and scope of the invention.

What is claimed is:

1. A coaxial light guide optical fiber structure, comprising an inner axial cladding, an annular core and an outer cladding, the annular core being interposed between the inner axial cladding and the outer cladding to provide light guide and having a refractive index greater than the inner axial cladding and the outer cladding that are made from pure undoped silicon dioxide, fused silica or other light guide materials to form a coaxial light guide structure, wherein:
refractive index profile of the optical fiber is set on the radius such that light transmits in a waveguide model arranged according to the coaxial light guide structure of the refractive index profile formed by the inner axial cladding and the outer cladding that have a same refractive index.

2. The coaxial light guide optical fiber structure of claim 1, wherein the optical fiber having a waveguide model arranged according to the refractive index profile is a single-mode waveguide coaxial light guide optical fiber.

3. The coaxial light guide optical fiber structure of claim 1, wherein the optical fiber having a waveguide model arranged according to the refractive index profile is a multimode waveguide coaxial light guide optical fiber.

4. The coaxial light guide optical fiber structure of claim 1, wherein the inner axial cladding and the outer cladding are undoped light guide material structures.

5. A coaxial semiconductor light source structure comprising an inner conductor and an outer conductor that are coaxial and mounted onto a substrate or a slab to provide electric power, and a plurality of coaxial annular semiconductor layers or conductor layers interposed between the inner conductor and the outer conductor; wherein:
two coaxial positive and negative electrodes supply electric power to the light emitting annular semiconductor layers to emit optical waves to an aligned coaxial optical fiber or a light receiving device.

6. The coaxial semiconductor light source structure of claim 5, wherein the light emitting structure between the coaxial positive electrode and the negative electrode is an organic or an inorganic coaxial light emitting diode that generates spontaneous emission resulting from the recombination of carrier.

7. The coaxial semiconductor light source structure of claim 5, wherein the light emitting structure between the coaxial positive electrode and the negative electrode is a coaxial semiconductor laser diode that generates stimulated emission resulting from the recombination of carrier.

8. A coaxial semiconductor photodiode comprising an inner conductor and an outer conductor that are coaxial and mounted onto a substrate to provide electric power, and a plurality of coaxial annular semiconductor layers or conductor layers interposed between the coaxial inner conductor and the outer conductor; wherein:
two coaxial positive and negative electrodes supply electric power to the annular semiconductor layers which detect light, the annular light detecting semiconductor layers having a depletion region to directly receive photon energy of optical wave transmitted from a coaxial optical fiber or image photon energy of an optical system thereby to detect a separated driving current through stimulated electrons and electric holes in an evenly built-in electric field within entire radii.

9. The coaxial semiconductor photodiode of claim 8, wherein the light detecting coaxial annular semiconductor layers between the two electrodes are a coaxial semiconductor PN photodiode which absorbs entered photons and generates a driving current of electrons and electric holes to detect light

10. The coaxial semiconductor photodiode of claim 8, wherein the light detecting coaxial annular semiconductor layers between the two electrodes are a coaxial semiconductor PIN photodiode which absorbs entered photons and generates a driving current of electrons and electric holes to detect light.

11. The coaxial semiconductor photodiode of claim 8, wherein the light detecting coaxial annular semiconductor layers between the two electrodes are a coaxial semiconductor APD avalanche photodiode which has an impact multiplication region to receive photons and generate high speed or high energy electrons and electric holes resulting from impact to ionize more new electrons and electric holes to form current multiplication to detect light.

12. A coaxial light guide system, comprising:
a coaxial semiconductor light source structure of claim 5; or
a coaxial light guide optical fiber structure of claim 1, or
a coaxial semiconductor photodiode of claim 8, wherein the coaxial semiconductor light source structure and the coaxial optical fiber structure are coupled, or the coaxial optical fiber structure and the coaxial semiconductor photodiode are coupled, or the coaxial optical fiber structure, the coaxial semiconductor light source structure and the coaxial semiconductor photodiode are coupled to perform communication and detection functions.

13. The coaxial light guide system of claim 12, wherein the coaxial semiconductor light source structure and the coaxial semiconductor photodiode are coaxially built on a same substrate to perform communication and detection functions of the coaxial light guide system.
